(19) United States
(12) Patent Application Publication
(10) Pub. No.: US 2008/0174952 A1
(43) Pub. Date: Jul. 24, 2008

(54) HEAT DISSIPATION ASSEMBLY

(75) Inventors: ZHEN-XING YE, Shenzhen (CN); KE SUN, Shenzhen (CN); MING-KE CHEN, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignees: HONG FU JIN PRECISION INDUSTRY (ShenZhen) CO., LTD, Shenzhen City (CN); HON HAI PRECISION INDUSTRY CO., LTD., Tu-Cheng (TW)

(21) Appl. No.: 11/857,452

(22) Filed: Sep. 19, 2007

(30) Foreign Application Priority Data
Jan. 24, 2007 (CN) 200710200104.7

(51) Int. Cl. H05K 7/20

(52) U.S. Cl. 361/687; 361/697; 361/704

(57) ABSTRACT

A heat dissipation assembly for dissipating heat generated on a motherboard, includes a clip attached to the motherboard and above a first heat-generating component, and a heat sink rotatably mounted to the clip and thermally connected with the first heat-generating component. The heat sink includes an air outlet. The air outlet is adjustable to face a second heat-generating component of the motherboard via rotating the heat sink, for more effective use of airflow coming from the heat sink to cool the second heat-generating component.

### BACKGROUND

1. Field of the Invention

The present invention relates to heat dissipation assemblies, and particularly to a heat dissipation assembly attached to a central processing unit (CPU).

2. Description of Related Art

Nowadays, computer systems are faster and more functional than ever before, which has lead to a great increase of heat coming from heat-generating components in the computer system, such as a CPU and a north bridge of a motherboard. Thus, a heat dissipation assembly is needed to reduce the temperature of the computer system. Generally, the heat dissipation assembly is mounted to the motherboard to cool the CPU, and a direction of an air outlet of the heat dissipation assembly is fixed. However, relative positions between the CPU and the north bridge are different on different standard motherboards. Thus, if the direction of an air outlet of the heat dissipation assembly cannot be changed, an airflow flowing out of the air outlet can't effectively cool the north bridges on different standard motherboards.

What is desired, therefore, is a heat dissipation assembly whose air outlet is changeable.

### SUMMARY

An exemplary heat dissipation assembly for dissipating heat for a printed circuit board (PCB), includes a clip attached to a side of the PCB that has a heat generating component mounted thereon, and a heat sink rotatably mounted to the clip, with a bottom contacting the heat-generating component.

Other advantages and novel features will become more apparent from the following detailed description when taken in conjunction with the accompanying drawings, in which:

### BRIEF DESCRIPTION OF THE DRAWINGS

FIG. 1 is an exploded, isometric view of a heat dissipation assembly in accordance with an embodiment of the present invention, the heat dissipation assembly including a heat sink;

FIG. 2 is an isometric view of the heat sink of FIG. 1, but an inverted view;

FIG. 3 is a partially assembled view of FIG. 1, together with a motherboard;

FIG. 4 is an assembled view of FIG. 3; and

FIG. 5 is similar to FIG. 4, but showing a different standard motherboard, with a north bridge in a position different from in FIG. 4.

### DETAILED DESCRIPTION

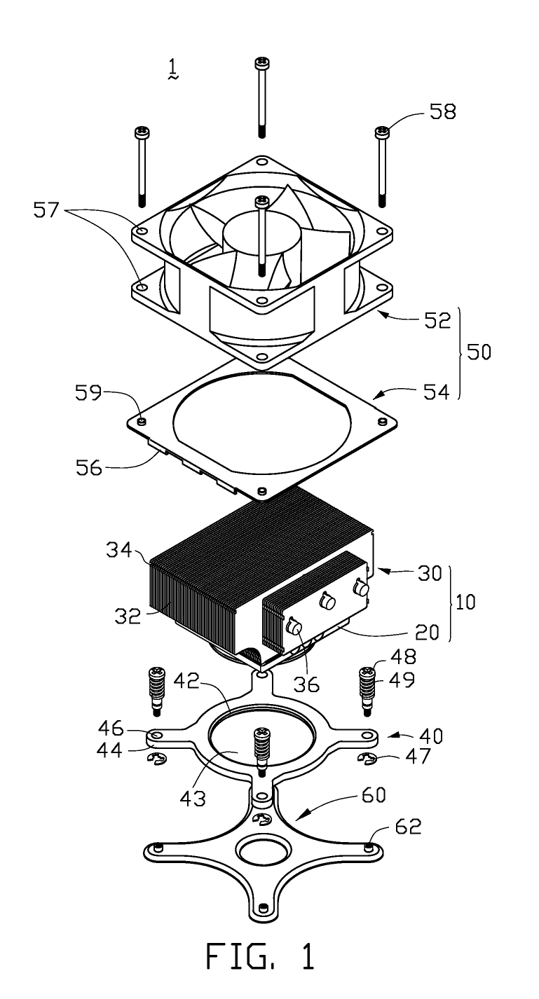

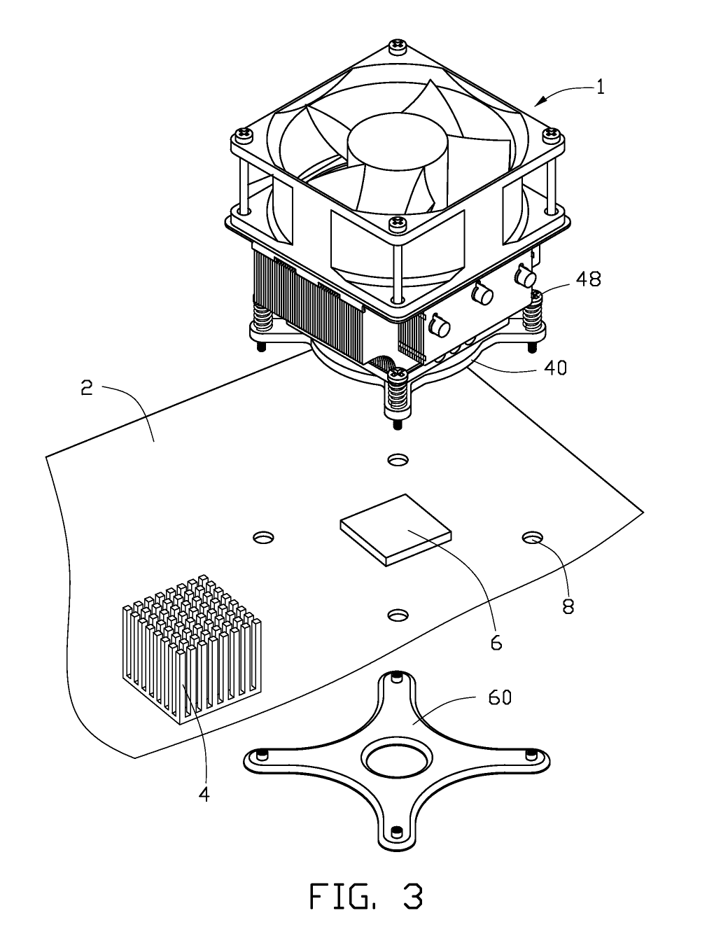

Referring to FIG. 1, a heat dissipation assembly 1 in accordance with an embodiment of the present invention includes a fan device 50, a heat sink 10, a clip 40, and a fixing board 60. The heat dissipation assembly 1 is configured for dissipating heat for a print circuit board, such as a motherboard 2 (shown in FIG. 3).

The fan device 50 includes a fan 52 and a rectangular plate 54. Four pairs of through holes 57 are respectively defined in four corners of the fan 52. The plate 54 includes a plurality of L-shaped hooks 56 extending down from two opposite sides thereof. An opening is defined in a center of the plate 54. Four mounting holes 59 are defined in four corners of the plate 54, respectively. In assembling the fan 52 and the plate 54 together, four screws 58 are inserted through the corresponding through holes 57 of the fan 52 and engaged in the corresponding mounting holes 59 of the plate 54.

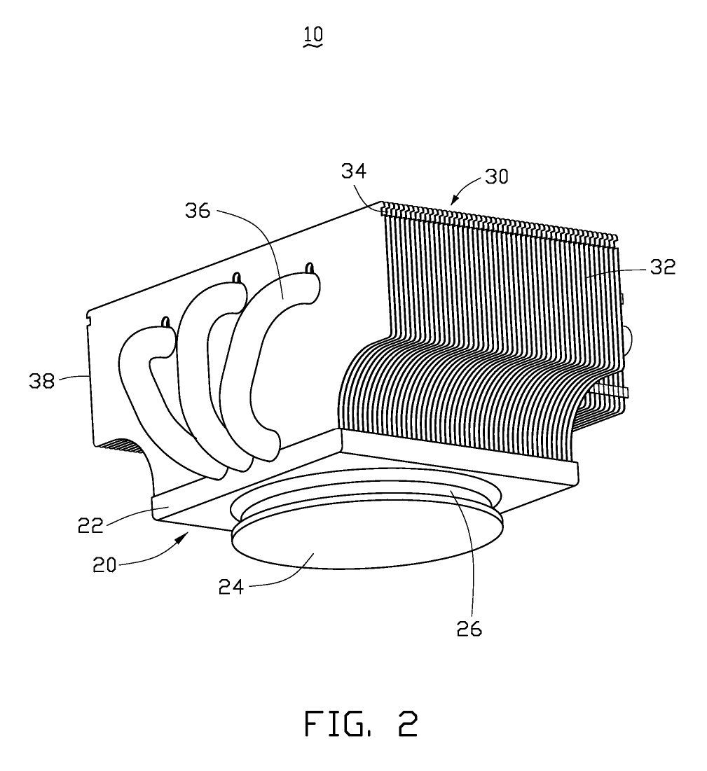

Referring also to FIG. 2, the heat sink 10 includes a base 20 for contacting a CPU 6 (shown in FIG. 3) of the motherboard 2 to transfer heat from the CPU 6, and a finned part 30. The base 20 includes a rectangular supporting part 22, and a circular connecting part 24 extending down from a bottom face of the supporting part 22. An annular groove 26 is defined in a circumference of the connecting part 24. The finned part 30 includes a plurality of parallel fins extending perpendicularly from a top surface of the supporting part 22, with two outlets 32, 38 formed at opposite ends thereof. A slot 34 is defined in an upper portion of the finned part at each of the air outlets 32, 38. A plurality of C-shaped heat pipes 36 is inserted in the heat sink 10, with middle portions thereof exposed at a side of the heat sink 10. An end of each heat pipe 36 is embedded in the upper portion of the finned part 30 and an opposite end of each pipe 36 is embedded between the finned part 30 and the base 20, which enhances heat exchange between the finned part 30 and the base 20.

The clip 40 includes a ring-shaped main portion 42 and four projecting portions 44 extending out from an outer side of the main portion 42. The main portion 42 is made to be slightly elastically deformable with material such as resin or hard plastic, and so on. A mounting hole 43 is defined in a center of the main portion 42. A locking hole 46 is defined in each projecting portion 44, with a fastening unit engaged therein. The fastening unit includes a screw 48 inserted in the locking hole 46, a spring 49 fitting about the screw 48 and located upon the projecting portion 44, and a clasp 47 clipped around the screw 48 and located under the projecting portion 44 for preventing the screw 48 from disengaging from the locking hole 46.

The fixing board 60 is generally cross-shaped, with an opening defined in a center and four fixing holes 62 respectively defined in four ends thereof.

Referring also to FIG. 3, in assembly, the hooks 56 of the plate 54 are engaged in the corresponding slots 34 of the finned part 30 of the heat sink 10 to combine the fan device 50 and the heat sink 10 together. A wall bounding the mounting hole 43 of the main portion 42 of the clip 40 is rotatably engaged in the groove 26 of the base 20 of the heat sink 10. The combined assembly of the fan device 50, the heat sink 10, and the clip 40 is placed upon the CPU 6 of the motherboard 2, with the screws 48 of the clip 40 respectively aligning with four through holes 8 defined in the motherboard 2 around the CPU 6. The fixing board 60 is attached to a bottom side of the motherboard 2. The screws 48 of the clip 40 are inserted through the corresponding through holes 8 of the motherboard 2 and engaged in the corresponding fixing holes 62 of the fixing board 60.

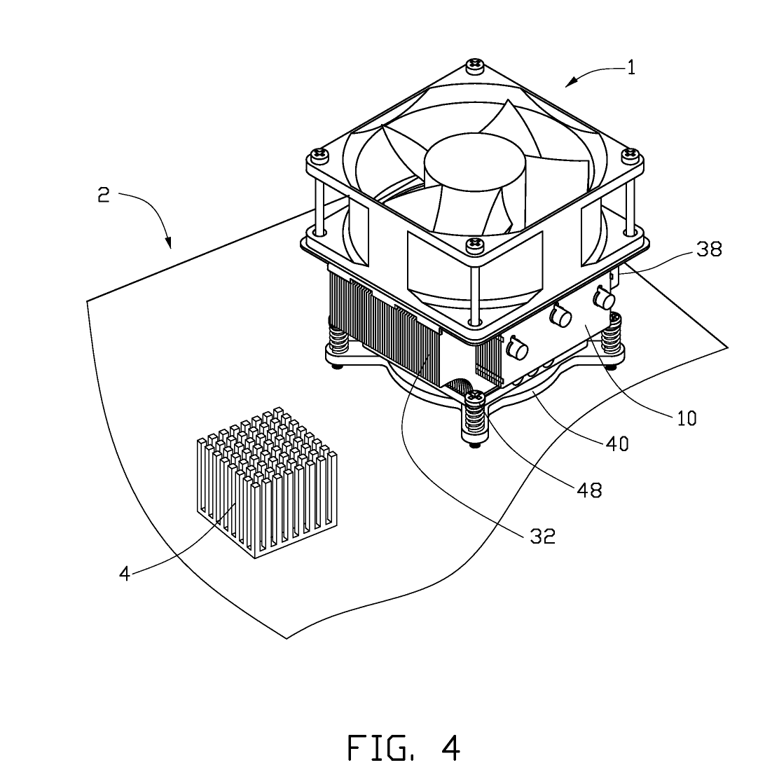

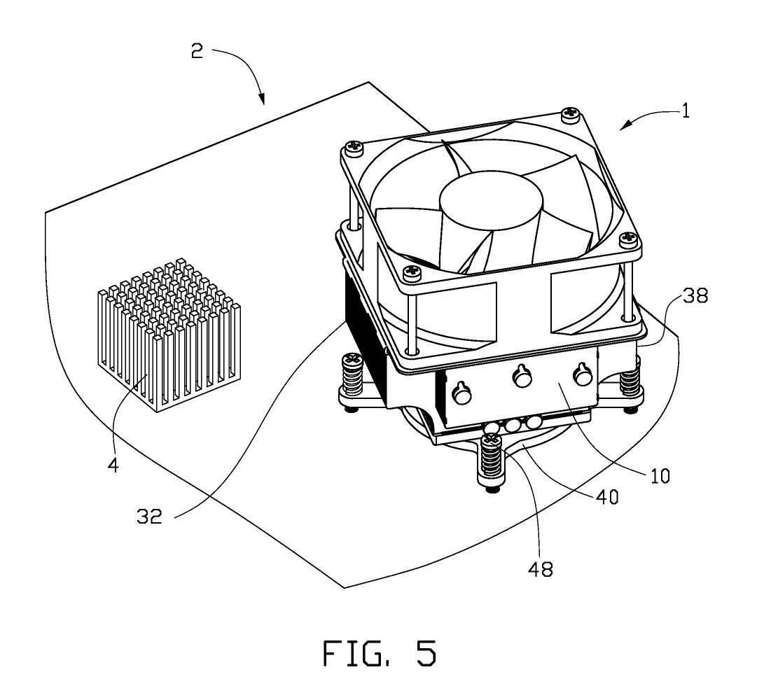

Referring to FIGS. 4 and 5, in use, the screws 48 of the clip 40 are relaxed in the corresponding fixing holes 62 of the fixing board 60, and the heat sink 10 is raised enough for the bottom of the base 20 to be clear of the CPU 6 and the heat sink 10 can then be rotated relative to the clip 40. Thus, the air outlet 32 of the heat sink 10 may be turned to face another heat sink 4 mounted on a north bridge according to different positions of the north bridge in different standard motherboards.

Additionally, one of the air outlets 32, 38 may be sealed and the other one of the air outlets 32, 38 facing the north bridge, to more effectively cool the north bridge.

It is believed that the present embodiments and their advantages will be understood from the foregoing description, and it will be apparent that various changes may be made thereto without departing from the spirit and scope of the invention or sacrificing all of its material advantages, the examples hereinbefore described merely being exemplary embodiments of the invention.

What is claimed is:

1. A heat dissipation assembly for dissipating heat for a printed circuit board, comprising:
a clip attached to a side of the printed circuit board that has a heat generating component mounted thereon; and
a heat sink rotatably mounted to the clip, with a bottom contacting the heat-generating component.

2. The heat dissipation assembly as claimed in claim 1, wherein the heat sink comprises a base defining a groove in a circumference thereof, the clip comprises a main portion defining a mounting hole, a wall bounding the mounting hole is rotatably engaged in the groove.

3. The heat dissipation assembly as claimed in claim 2, wherein the main portion is made of slightly elastically deformable material such that the main portion is deformable to enlarge the mounting hole to allow the base entering therethrough and returnable to reduce the mounting hole to allow the wall of the main portion being engaged in the groove of the base.

4. The heat dissipation assembly as claimed in claim 2, wherein the heat sink further comprises a finned part fixed to the base, at least one air outlet is formed on the finned part.

5. The heat dissipation assembly as claimed in claim 4, wherein the finned part comprises a plurality of parallel fins extending perpendicularly from the base, said at least one air outlet is formed at corresponding ends of the fins.

6. The heat dissipation assembly as claimed in claim 5, wherein two air outlets are respectively formed on opposite ends of the fins.

7. The heat dissipation assembly as claimed in claim 6, further comprising a fan device, wherein the fan device is mounted to the finned part of the heat sink and configured for supplying airflow to the heat sink.

8. The heat dissipation assembly as claimed in claim 7, wherein a slot is defined in an upper portion of the finned part at each of the air outlets of the heat sink, the fan device comprises a fan and a plate configured for mounting the fan to the finned part, the plate comprises a plurality of hooks extending down from two opposite sides thereof, the hooks are engaged in the corresponding slots of the heat sink.

9. The heat dissipation assembly as claimed in claim 7, still further comprising a plurality of C-shaped heat pipes, wherein the heat pipes are inserted in the heat sink, with middle portions thereof exposed at a side of the heat sink, and an end of each of the heat pipes is embedded in an upper portion of the finned part, and an opposite end of each of the heat pipes is embedded between the finned part and the base.

10. The heat dissipation assembly as claimed in claim 1, further comprising a fixing board, wherein the fixing board is attached to an opposite side of the printed circuit board, and fixed to the clip.

11. The heat dissipation assembly as claimed in claim 10, wherein the clip comprises a plurality of projecting portions extending out from an outer side of the main portion, a locking hole is defined in each of the projecting portions with a fastening unit engaged therein, the fastening unit includes a screw inserted in the locking hole and a spring fitting about the screw and located upon the projecting portion, a plurality of fixing holes is defined in the fixing board, the screws are inserted through the printed circuit board to engage in the corresponding fixing holes of the fixing board.

12. An assembly comprising:
a printed circuit board with a first heat-generating component and a second heat-generating component mounted on a side thereof;
a clip attached to the printed circuit board and above the first heat-generating component; and
a heat sink rotatably mounted to the clip and thermally connected with the first heat-generating component, the heat sink comprising an air outlet, orientation of the air outlet being adjustable to face the second heat-generating component via rotating the heat sink relative to the printed circuit board.

13. The assembly as claimed in claim 12, wherein the heat sink comprises a base, a round groove is defined in a circumference of the base, the clip comprises a main portion defining a round mounting hole therein, a wall of the main portion bounding the mounting hole is rotatably engaged in the groove.

14. The assembly as claimed in claim 13, wherein the heat sink further comprises a finned part fixed to the base, the air outlet is formed at one side of the finned part.

15. The assembly as claimed in claim 14, wherein the finned part comprises a plurality of parallel fins extending perpendicularly from the base, a plurality of airflow passages is formed between adjacent fins, and the air outlet is formed at corresponding ends of passages.

16. The assembly as claimed in claim 15, further comprising a fan device, wherein the fan device is mounted to the finned part of the heat sink to supply airflow to the heat sink.

17. The assembly as claimed in claim 16, wherein the printed circuit board is a motherboard of a computer, the first heat-generating component is a central processing unit, and the second heat-generating component is a north bridge.

18. An assembly comprising:
a circuit board with a first heat-generating component and a second heat-generating component mounted on a side thereof;
a heat sink configured to dissipating heat from the first heat-generating component, the heat sink comprising a plurality of parallel fins, a passage being formed between every two adjacent fins and having an outlet; and
a clip fixed to the circuit board and configured to secure the heat sink to the first heat-generating component in such a manner that the heat sink is rotatable relative to the clip to adjust orientation of the outlets to face the second heat-generating component.

19. The assembly as claimed in claim 18, wherein the heat sink further comprises a base defining a round groove, the clip comprises a main portion defining a round mounting hole therein, and a wall of the main portion bounding the mounting hole is rotatably engaged in the groove.

20. The assembly as claimed in claim 19, wherein the main portion is made of slightly elastically deformable material such that the main portion is deformable to enlarge the mounting hole to allow the base entering therethrough and returnable to reduce the mounting hole to allow the wall of the main portion being engaged in the groove of the base.

21. The assembly as claimed in claim 18, further comprising a fixing board disposed at an opposite side of the circuit board, wherein the clip further comprises a plurality of projecting portions extending radially out from an outer side of the main portion, a plurality of fastening elements respectively extends through the projecting portions to engage with the fixing board, and a plurality of elastic member is respectively compressed between the fastening elements and projecting portions.
